(19) United States
(12) Patent Application Publication
(10) Pub. No.: US 2009/0087970 A1
(43) Pub. Date: Apr. 2, 2009

(54) Method of producing a dopant gas species

(75) Inventors: Gregory Robert Alcott, Liphook, NH (US); Christopher Burgess, Austin, TX (US)

Correspondence Address: APPLIED MATERIALS, INC., P. O. BOX 450A, SANTA CLARA, CA, 95052, US

(73) Assignee: APPLIED MATERIALS, INC.

(21) Appl. No.: 11/905,165

(22) Filed: Sep. 27, 2007

(51) Int. Cl. H01L 21/265; C07F 5/02; H01L 21/67

(52) U.S. Cl. 438/514; 568/3; 29/25.01; 257/E21.334

(57) ABSTRACT

This invention relates to a method of producing B₂H₆ (diborane) in semiconductor wafer processing apparatus. In particular, although not exclusively, this invention relates to producing a dopant gas species containing a desired dopant element, and then producing dopant ions for implanting in semiconductor wafers using an ion implanter. The present invention provides such a method by passing a flow of a boron containing gas such as BF₃ over a hydrogen containing solid such as NaH thereby forming an outflow of B₂H₆.

### FIELD OF THE INVENTION

This invention relates to a method of producing B₂H₆ (diborane) in semiconductor wafer processing apparatus. In particular, although not exclusively, this invention relates to producing a dopant gas species containing a desired dopant element, and then producing dopant ions for implanting in semiconductor wafers using an ion implanter.

### BACKGROUND OF THE INVENTION

The semiconductor industry has a requirement for the production of semiconductor devices that is most often met by fabrication of arrays of many devices on a single wafer. These wafers undergo a range of treatments, some of which may involve the use of boron. For example, semiconductor devices often require doping to very fine tolerances to achieve desired characteristics, and boron is a commonly used dopant. Such doping may be performed using an ion implanter that comprises an ion source to generate ions corresponding to, or containing, boron or another dopant. Optics then form the ions into a focussed ion beam that is incident upon the wafer. Control of the ion beam (e.g. beam current, ion content, energy, size, scanning, etc.) is of paramount importance as this determines the dopant concentration in the wafer and also the depth of implant, thereby determining the conductive properties of the devices.

Bottles are generally used as a supply of a boron-containing gas, e.g. B₂H₆. These bottles are connected to the ion source such that the gas is allowed to enter an arc chamber where an arc discharge ionises the gas to form a plasma. An extraction electrode is used to extract ions from the arc chamber through an aperture provided therein. Further electrodes are used to form an ion beam that is directed at the wafer to be implanted. Generally, the ion beam passes through a mass-analysing magnet that selects only ions with the desired mass-to-charge ratio: put another way, the mass-analysing magnet effectively rejects unwanted ions that are inevitably produced in the arc chamber/plasma or otherwise generated.

### SUMMARY OF THE INVENTION

Against this background, and from a first aspect, the present invention resides in a method of producing B₂H₆ in situ in semiconductor processing apparatus, comprising passing a flow of a boron containing gas over a hydrogen containing solid thereby forming an outflow of B₂H₆.

As a result, more commonly available gases may be used as a feed gas for producing B₂H₆ in situ. For example, a gaseous boron halide such as BF₃ or BCl₃ may be used as a feed gas.

Various hydrogen containing solids may be used with the method, such as solid hydrides. Metal hydrides, and the alkali metal hydrides are currently preferred, with NaH or KH being the most preferred.

Optionally, the method further comprises heating the hydrogen containing solid while passing the gas thereover. Preferably, the hydrogen containing solid is heated to 150° C. to 200° C., substantially 180° C. being particularly preferred.

The outflow of B₂H₆ may be cooled. This mitigates against the chances of decomposition or polymerisation.

Optionally, the method may comprise purging a vessel in which the hydrogen containing solid is contained by passing a flow of an inert gas through the vessel.

From a second aspect, the present invention resides in a method of producing B₂H₆ in situ in semiconductor processing apparatus, comprising: heating a vessel containing NaH, and passing a flow of BF₃ over the NaH contained in the vessel thereby forming a flow of B₂H₆ out of the vessel. Hence, commonly available BF₃ may be used as a feed gas for producing B₂H₆ in situ. The BF₃ may be supplied from an SDS type bottle.

Preferably, the NaH in the vessel is heated to 150° C. to 200° C., 180° C. being particularly preferred.

Optionally, the flow of BF₃ may be regulated using a mass flow controller.

Preferably, the flow of B₂H₆ is cooled after it leaves the vessel. This mitigates against the chances of decomposition or polymerisation.

Optionally, the vessel may be purged by passing a flow of an inert gas such as Ar over the NaH in the vessel. This assists in removing any deposits that may have formed.

The semiconductor processing apparatus may be an ion implanter. The B₂H₆ produced according to the above methods may be used for B₂ diamer implants.

According to a third aspect, a method of implanting a semiconductor wafer, comprising: producing B₂H₆ according to any preceding claim; introducing the B₂H₆ into an ion source; operating the ion source thereby producing an ion beam; and guiding the ion beam to a semiconductor wafer to be incident thereon.

The NaH in the vessel may be heated to 150° to 200° C., substantially 180° C. being particularly preferred.

Optionally, the flow of BF₃ is regulated using a mass flow controller. The flow of B₂H₆ may be cooled after it leaves the vessel. The BF₃ may be supplied from a SDS bottle.

Optionally, the method may further comprise purging the vessel by passing a flow of an inert gas such as Ar over the NaH in the vessel.

Optionally, the ion source comprises an arc chamber, and the method comprises generating a plasma in the arc chamber. An indirectly-heated cathode may be used. The method may comprise guiding the ion beam through a mass analyser placed on the ion beam path to the semiconductor wafer, and mass selecting ions of a desired mass to charge ratio. For example, B₂ diamer ions may be mass selected.

From a fourth aspect, the present invention resides in semiconductor processing apparatus including a B₂H₆ source comprising: a source of a boron containing gas; a vessel containing a hydrogen containing solid that is coupled to the source of the boron containing gas via a gas flow regulator; a heater for heating the hydrogen containing solid in the vessel; and a conduit arranged to convey the outflow of B₂H₆ from the vessel.

Optionally, the source of a boron containing gas is a boron halide source, such as a BF₃ or BCl₃ source.

The vessel may contain a solid hydride, such as a metal hydride like an alkali metal hydride. NaH and KH are particularly preferred.

The vessel may be a heated column or a conversion column. The apparatus may further comprise a cooler for cooling the flow of B₂H₆ through the conduit. The gas flow regulator may be a mass flow controller. The BF₃ source may be a SDS type bottle.

The apparatus may further comprise an inert gas source coupled to the vessel via a gas flow regulator. The inert gas source may be an argon source, optionally a SDS bottle of Ar.

The semiconductor processing apparatus may be an ion implanter. The ion implanter may further comprise an ion source arranged to receive the flow of B₂H₆ from the conduit and to generate ions therefrom, and means for guiding ions generated by the ion source to a semiconductor wafer to be incident thereon. The ion source may comprise an arc chamber and, optionally, an indirectly heated cathode. The ion implanter may further comprise a mass analyser positioned on the ion path from the ion source to the semiconductor wafer.

### BRIEF DESCRIPTION OF THE DRAWINGS

In order that the invention can be more readily understood, reference will now be made, by way of example only, to the accompanying drawings, in which:

FIG. 1 is a schematic view of an ion implanter according to an embodiment of the present invention; and

FIG. 2 is a simplified view of an ion source according to an embodiment of the present invention.

### DETAILED DESCRIPTION OF THE INVENTION

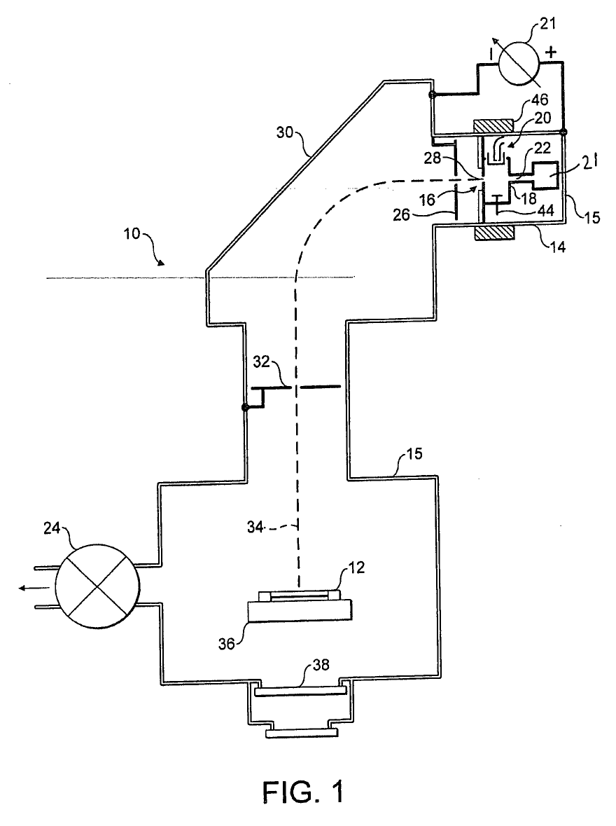

An ion implanter 10 for implanting ions in semiconductor wafers 12 is shown in FIG. 1 that includes an ion source 14 according to the present invention. Ions are generated by the ion source 14 to be extracted and passed through a mass analysis stage 30. Ions of a desired mass-to-charge ratio are selected to pass through a mass-resolving slit 32 and then to strike a semiconductor wafer 12.

The ion implanter 10 contains an ion source 14 for generating an ion beam of a desired species that is located within a vacuum chamber 15. The ion source 14 generally comprises an arc (or discharge or ionisation) chamber 16 containing an indirectly-heated cathode 20 located at one end thereof and an anode that is provided by the walls 18 of the arc chamber 16. The cathode 20 is heated sufficiently to generate thermal electrons.

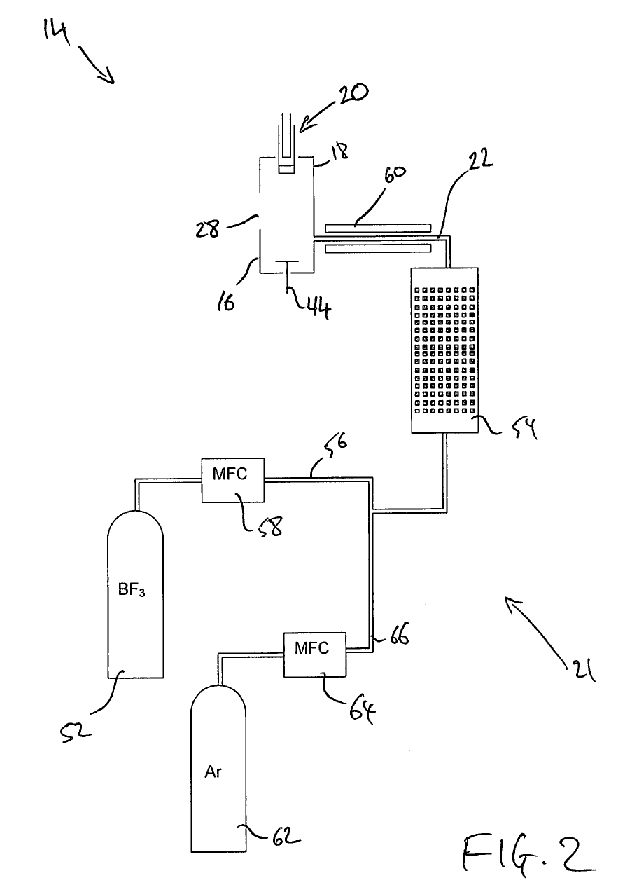

Thermal electrons emitted by the cathode 20 are attracted to the anode, i.e. the adjacent chamber walls 18. The thermal electrons ionise gas molecules as they traverse the arc chamber 16, thereby forming a plasma and generating the desired ions. The gas molecules are produced at 21, as will be described in more detail with reference to FIG. 2, and drift into the arc chamber 16 through gas feed 22.

The path followed by the thermal electrons is controlled to prevent the electrons merely following the shortest path to the chamber walls 18. A magnet assembly 46 provides a magnetic field extending through the arc chamber 16 such that thermal electrons follow a spiral path along the length of the arc chamber 16 towards a counter-cathode 44 located at the opposite end of the arc chamber 16.

A gas feed 22 fills the arc chamber 16 with a precursor gas species. The thermal electrons travelling through the arc chamber 16 ionise the precursor gas molecules and possibly also crack the precursor gas molecules as well to form other ions. The ions created in the plasma will also contain trace amounts of contaminant ions (e.g. generated from the material of the chamber walls).

Ions from within the arc chamber 16 are extracted through an exit aperture 28 using a negatively-biased extraction electrode 26. A potential difference is applied between the ion source 14 and the following mass analysis stage 30 by a power supply 21 to accelerate extracted ions, the ion source 14 and mass analysis stage 30 being electrically isolated from each other by an insulator (not shown). The mixture of extracted ions are then passed through the mass analysis stage 30 so that they pass around a curved path under the influence of a magnetic field. The radius of curvature traveled by any ion is determined by its mass, charge state and energy. The magnetic field is controlled so that, for a set beam energy, only those ions with a desired mass and charge state exit along a path coincident with the mass-resolving slit 32. The emergent ion beam 34 is then transported to the target, i.e. one or more semiconductor wafers 12 to be implanted or a beam stop 38 when there is no wafer 12 in the target position. In other modes, the beam 34 may also be decelerated using a lens assembly positioned between the mass analysis stage 30 and the target position.

An ion source 14 suitable for use in the ion implanter 10 of FIG. 1 is shown in schematic form in FIG. 2. The ion source 14 includes an arc chamber 16 connected to a gas supply 21 by gas feed 22. The gas supply 21 comprises apparatus for in situ production of B₂H₆. The feed gas is a SDS-type bottle shown at 52, and contains BF₃ in this embodiment. The BF₃ bottle 52 is connected to a conversion column 54 via line 56. Flow of the BF₃ through the line 56 to the conversion column 54 is controlled using a mass flow controller 58.

In this embodiment, the conversion column 54 contains NaH and is heated to a temperature of 180° C. Passing the BF₃ feed gas over the NaH at the elevated temperature results in the following reaction:

2BF₃+6NaH|B₂H₆+6NaF

Accordingly, an outflow of B₂H₆ is obtained from the conversion column 54 that is conveyed to the arc chamber 16 via gas feed 22. The flow of B₂H₆ in gas feed 22 is cooled, for example by using a water chiller, or other means, shown at 60. Cooling the B₂H₆ is advantageous as it prevents decomposition or polymerisation while being conveyed to the arc chamber 16.

The by-product of the above reaction (NaF) is a stable, low-volatility salt that remains within the conversion column 54. This is advantageous as it removes the need to separate and purify the product gas. As NaH will be consumed during operation of the gas supply 21, the conversion column 54 will need to be replaced from time to time.

In addition, it is preferred to be able to purge the system and, to this end, an SDS bottle 62 containing Ar gas is provided. Flow of Ar gas from the bottle 62 is regulated by a mass flow controller 64, as shown in FIG. 2. A line 66 connects the Ar bottle 62 and mass flow controller 64 to the line 56 leading from the BF₃ bottle 52 to the conversion column 54. With this arrangement Ar may be admitted into the system, thereby purging the system. This may be performed, for example, following a change of conversion column 54 or BF₃ gas bottle 52. Purging may also be performed periodically.

Those skilled in the art will appreciate that variations may be made to the above embodiments without departing from the scope of the present invention.

While the above embodiment sets the present invention in the context of an ion implanter 10, it will be appreciated that the present invention may find application in other semiconductor wafer processes.

In addition to using BF₃ as the feed gas, other boron containing gases may be used such as other boron halides like BCl₃. Similarly, alternatives to NaH may be used. Alternatives include hydrogen containing solids such as metal hydrides. Alkali hydrides like KH would make good alternatives.

While Ar has been described as the purge gas, other inert gases could be suitable alternatives. While the conversion column 54 has been described as being heated to 180° C., other temperatures could be used. Although cooling the B₂H₆ flow in the gas feed 22 is described above, this is but merely a preferred feature and may be omitted if desired.

The ion source 14 comprises an arc chamber 16 having an indirectly heated cathode 20. Details of the actual ion source may be varied, for example a Bernas cathode may be used instead. The inclusion or not of a counter cathode 44 is also optional, and various biasing arrangements may be used in the arc chamber 16.

1-25. (canceled)

26. A method of producing B₂H₆ in situ in semiconductor processing apparatus, comprising passing a flow of a boron-containing gas over a hydrogen-containing solid and thereby forming an outflow of B₂H₆.

27. The method of claim 26, wherein passing a flow of a boron-containing gas over a hydrogen-containing solid comprises passing the gas over a compound selected from the group consisting of a solid hydride, a metal hydride, an alkali metal hydride, NaH and KH.

28. The method of claim 26, further comprising heating the hydrogen-containing solid while passing the gas thereover.

29. The method of claim 28, further comprising heating the hydrogen-containing solid to a temperature of 150° C. to 200° C.

30. The method of claim 29, wherein said temperature is about 180° C.

31. The method of claim 26, wherein passing a flow of a boron-containing gas over a hydrogen-containing solid comprises passing over the solid compound selected from the group consisting of a gaseous boron halide, BF₃ and BCl₃.

32. The method of claim 26, further comprising cooling the outflow of B₂H₆.

33. The method of claim 26, further comprising purging a vessel in which the hydrogen-containing solid is contained by passing a flow of an inert gas through the vessel.

34. A method of producing B₂H₆ in situ in semiconductor processing apparatus, comprising heating a vessel containing NaH, and passing a flow of BF₃ over the NaH contained in the vessel, thereby forming a flow of B₂H₆ out of the vessel.

35. The method of claim 34, further comprising heating the NaH in the vessel to a temperature of 150° C. to 200° C.

36. The method of claim 35, wherein said temperature is about 180° C.

37. The method of claim 34, further comprising cooling the flow of B₂H₆ after it leaves the vessel.

38. The method of claim 34, further comprising purging the vessel by passing a flow of an inert gas over the NaH in the vessel.

39. The method of claim 34, wherein the semiconductor processing apparatus is an ion implanter.

40. A method of implanting a semiconductor wafer, comprising:
producing B₂H₆ according to claims 26 or 34;
introducing the B₂H₆ into an ion source;
operating the ion source thereby producing an ion beam; and
guiding the ion beam to a semiconductor wafer to be incident thereon.

41. The method of claim 40, wherein the ion source comprises an arc chamber, and the method further comprises generating a plasma in the arc chamber.

42. The method of claim 40, comprising guiding the ion beam through a mass analyzer placed on the ion beam path to the semiconductor wafer, and mass selecting ions of a desired mass-to-charge ratio.

43. The method of claim 42, comprising selecting B₂ diamer ions.

44. Semiconductor processing apparatus including a B₂H₆ source comprising:
a source of a boron-containing gas;
a vessel containing a hydrogen-containing solid that is coupled to the source of the boron-containing gas via a gas flow regulator;
a heater for heating the hydrogen-containing solid in the vessel; and
a conduit arranged to convey the outflow of B₂H₆ from the vessel.

45. The apparatus of claim 44, wherein the source of a boron-containing gas is a compound selected from the group consisting of a boron halide source, a BF₃ source and a BCl₃ source.

46. The apparatus of claim 44, wherein the vessel contains a compound selected from the group consisting of a solid hydride, a metal hydride, NaH and KH.

47. The apparatus of claim 44, wherein the vessel is a heated column.

48. The apparatus of claim 44, further comprising a cooler for cooling the flow of B₂H₆ through the conduit.

49. The apparatus of claim 44, further comprising an inert gas source coupled to the vessel via a gas flow regulator.

50. The apparatus of claim 44, wherein the semiconductor processing apparatus is an ion implanter.

51. The apparatus of claim 50, further comprising an ion source arranged to receive the flow of B₂H₆ from the conduit and to generate ions therefrom, and means for guiding ions generated by the ion source to a semiconductor wafer to be incident thereon.

52. The apparatus of claim 51, further comprising a mass analyzer positioned on the ion path from the ion source to the semiconductor wafer.
